(19) United States
(12) Patent Application Publication
(10) Pub. No.: US 2025/0166959 A1
(43) Pub. Date: May 22, 2025

(54) HIGH BANDWIDTH VARIABLE DOSE ION IMPLANTATION SYSTEM AND METHOD

(71) Applicant: Axcelis Technologies, Inc., Beverly, MA (US)

(72) Inventor: Andy Ray, Newburyport, MA (US)

(21) Appl. No.: 18/934,357

(22) Filed: Nov. 1, 2024

Related U.S. Application Data
(60) Provisional application No. 63/599,710, filed on Nov. 16, 2023.

(51) Int. Cl. H01J 37/147; H01J 37/317

(52) U.S. Cl. CPC H01J 37/1471; H01J 37/1472; H01J 37/3171; H01J 2237/30483

(57) ABSTRACT

An ion implantation system includes an ion source that generates ions and produces an ion beam along a beamline, a mass analyzer positioned downstream of the ion source that generates a magnetic field according to a selected charge-to-mass ratio. A beamline formed by ion beam is directed to a workpiece target. A gating apparatus includes one or more of: a mechanical gating device configured to block or deflect the ion beam from contacting a workpiece target; or a power control gating device configured to cut off power to the ion source. The beam-to-workpiece target translation mechanism changes the beam-to-workpiece target position while the ion beam is gated by the gating apparatus. Methods for implanting ions in predetermined profiles on a workpiece are disclosed with multiple scans. These systems and methods allow for implantation profiles with smooth curvature and/or sharp differences in dosage characteristics at adjacent positions.

### CROSS-REFERENCE TO RELATED APPLICATIONS

This application claims priority to U.S. provisional application No. 63/599,710, filed Nov. 16, 2023, titled HIGH BANDWIDTH VARIABLE DOSE ION IMPLANTATION SYSTEM AND METHOD. This prior application is incorporated herein by reference for all purposes.

### FIELD

The present disclosure relates generally to ion implantation systems, and more particularly to an ion implantation system with controlled dosing capabilities.

### BACKGROUND

In the manufacture of semiconductor devices, ion implantation is used to dope semiconductors with impurities. Ion implantation systems are often utilized to dope a workpiece, such as a semiconductor wafer, with ions from an ion beam, in order to either produce n- or p-type material doping, or to form passivation layers during fabrication of an integrated circuit. Such beam treatment is often used to selectively implant the wafers with impurities of a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. When implanting ions into silicon wafers, ions generated from source materials such as antimony, arsenic, or phosphorus, for example, results in an “n-type” extrinsic material wafer, whereas a “p-type” extrinsic material wafer often results from ions generated with source materials such as boron, gallium, or indium. When implanting ions into silicon carbide (SiC) wafers, for example, nitrogen (n-dopant) and aluminum (p-dopant) are conventionally used as ion species.

A typical ion implanter includes an ion source, an ion extraction device, a mass analysis device, with or without a post acceleration section, a beam transport device, and a wafer processing device. The ion source generates ions of desired atomic or molecular dopant species. These ions are extracted from the ion source by the ion extraction device, which are typically a set of electrodes that energize and direct the flow of ions from the ion source, forming an ion beam. Desired ions are separated from the ion beam in the mass analysis device, which is typically a magnetic dipole performing mass dispersion or separation of the extracted ion beam. The beam transport device, which is typically a vacuum system containing a series of focusing and acceleration/deceleration devices, transports the analyzed ion beam to the wafer processing device while maintaining desired properties of the ion beam. Finally, semiconductor wafers are transferred into and out of the wafer processing device via a wafer handling system, which may include one or more robotic arms, for placing a wafer to be treated in front of the analyzed ion beam and removing treated wafers from the ion implanter.

For many ion implantation systems, the physical size of the ion beam is smaller than a target workpiece, whereby the ion beam is scanned in one or more directions in order to adequately cover a surface of the target workpiece. Generally, an electrostatic or magnetic based beam scanner scans the ion beam in a fast direction and a mechanical device moves the target workpiece in a slow scan direction in order to provide sufficient coverage of the ion beam across the surface of the workpiece.

Traditionally ion implantation is targeted to provide uniform implantation across a wafer, but increasingly complex demands for applications require the dose to be a specific profile. This can be implemented by varying the beam-to-workpiece target speed. However, a drawback to that approach is dose variability is limited due to the range of scanning speed of the systems used to either scan the beam or workpiece. This range of scan speed is typically determined by the bandwidth of the system (electric, magnetic, or mechanical scanning speed of the wafer or beam).

### SUMMARY

The present disclosure appreciates that significant demands for an ion implantation system call for producing a variable or controlled dose to provide highly accurate and predetermined implants. As such, systems and methods for providing a variable or controlled dose in a manner that allows for precise doping into desired profiles are provided herein.

Accordingly, the following presents a simplified summary of the disclosure in order to provide a basic understanding of some aspects of the disclosure. This summary is not an extensive overview of the disclosure. It is intended to neither identify key or critical elements of the invention nor delineate the scope of the invention. Its purpose is to present some concepts of the disclosure in a simplified form as a prelude to the more detailed description that is presented later.

In some aspects, the techniques described herein relate to an ion implantation system, including: an ion source that generates ions and produces an ion beam along a beamline; a workpiece target associated with the beamline; a controller configured to control a beam-to-workpiece target translation mechanism to move the ion beam in relation to a workpiece target, thereby moving a beam-to-workpiece target position at a beam-to-workpiece target speed; and a gating apparatus including one or more of: a mechanical gating device configured to block or deflect the ion beam from being directed to the workpiece target; a power control gating device configured to cut off power to the ion source; or a magnetic, electromagnetic, or electric beam deflection device configured to deflect the ion beam from being directed to the workpiece target; wherein the beam-to-workpiece target translation mechanism changes the beam-to-workpiece target position while the ion beam is gated by the gating apparatus.

In some aspects, the techniques described herein relate to a method of conducting ion implantation including: generating an ion beam; moving an ion beam in relation to a workpiece target in a first scan, thereby moving a beam-to-workpiece target position at a first beam-to-workpiece target speed; and during the first scan, gating the ion beam while continuing to move the beam-to-workpiece target position.

The above summary is merely intended to give a brief overview of some features of some embodiments of the present disclosure, and other embodiments may comprise additional and/or different features than the ones mentioned above. In particular, this summary is not to be construed to be limiting the scope of the present application. Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings. Furthermore, the features of the various embodiments and examples described herein may be combined with each other unless specifically noted otherwise.

### BRIEF DESCRIPTION OF THE DRAWINGS

FIG. 1A is a simplified top view illustrating an ion implantation system in accordance with an aspect of the present disclosure.

FIG. 1B is a schematic block diagram illustrating an example of a beam control circuit of an ion implantation system used to initiate or terminate the ion beam by switching the extraction and/or suppression voltages to the respective electrodes associated with an ion source of the ion implantation system.

FIG. 2 is a graph showing a desired dose profile in comparison to a required beam-to-workpiece target speed profile.

FIG. 3 is a graph showing a desired total dose profile overlaid with a first pattern 302 and a second pattern 304 with the relative dose on the y-axis and the wafer position on the x-axis.

FIG. 4 is a graph showing first through tenth scan patterns 401-410 with the relative dose on the y-axis and the wafer position on the x-axis.

FIG. 5 is a graph showing first through scan tenth patterns 501-510 with the relative dose on the y-axis and the wafer position on the x-axis.

FIG. 6 is a graph showing first through twentieth scan patterns 601-620 with the normalized dose on the y-axis and the wafer position on the x-axis.

FIG. 7 is a graph showing first through twentieth scan patterns 701-720 with a 100 mm ion beam with the normalized dose on the y-axis and the wafer position on the x-axis.

FIG. 8 is a graph like FIG. 7 but with the scan patterns removed, showing just the desired and predicted actual doses with a 100 mm beam.

FIG. 9 is a graph showing first through twentieth scan patterns 901-920 with the normalized dose on the y-axis and the wafer position on the x-axis.

FIG. 10 shows the actual ion implantation dosage on a wafer, measured after a set of patterns as shown in FIG. 9 were executed.

FIG. 11 is a graph like FIG. 10 but with the patterns removed, showing just the desired 1102 and actual 1104 observed doses with a 100 mm beam.

FIG. 12 is a flowchart of an example method for conducting ion implantation.

FIG. 13 is a flowchart of an example method for conducting ion implantation focusing on beam calibration and calculation of set scan patterns to achieve a desired dosage profile.

### DETAILED DESCRIPTION

The present disclosure is directed generally toward various apparatuses, systems, and methods associated with implantation of ions into a workpiece. More specifically, the present disclosure is directed to an ion implantation system and method for providing a controlled or variable dose to fit a predetermined profile.

Accordingly, the technology is described with reference to the drawings, wherein like reference numerals may be used to refer to like elements throughout. It is to be understood that the description of these aspects is merely illustrative and that they should not be interpreted in a limiting sense. In the following description, for purposes of explanation, numerous specific details are set forth in order to provide a thorough understanding of the technology described herein. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as exemplary only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components for all embodiments encompassed by this disclosure.

It is also to be understood that in the following description, any direct connection or coupling between functional blocks, devices, components, or other physical or functional units shown in the drawings or described herein could also be implemented by an indirect connection or coupling. Furthermore, it is to be appreciated that functional blocks or units shown in the drawings may be implemented as separate features or components in one embodiment, and may also or alternatively be fully or partially implemented in a common feature or component in another embodiment.

The terms workpiece and workpiece support are used herein with recognition that a workpiece will be a utilized in operation, but a workpiece support is used to hold and position the workpiece. Furthermore, ion implantation systems may be produced with workpiece supports that are configured to hold workpieces, but are not typically manufactured or sold with workpieces. Thus, discussion of a workpiece and how the beam or components of the ion implantation systems disclosed herein relate to a workpiece should also be understood to be disclosed in terms of the workpiece support. The term “workpiece target” is used herein to mean either a workpiece if the workpiece is in place on the workpiece support or the location where a workpiece is configured to be held by a workpiece support.

Most conventional ion implantation systems require a highly uniform dosage. Changes in dosage profile can be accomplished by varying the beam-to-workpiece target speed. Physical masks placed over the wafer itself can also be applied, but this is inefficient and costly at large scale. This solution also lacks flexibility in creating different patterns. In contrast, the systems and methods disclosed herein operate to provide an uneven dosage to match a specialized ion implantation profile. The desired pre-determined dosage profile can be accurately replicated with multiple passes and employing a gated beamline. The technology disclosed herein also allows for regions of no dosage or very different dosage without employing physical masks on the workpiece target.

Such techniques can be utilized to mitigate the effect of spatial variation in one or more other process steps during semiconductor device manufacturing. For example, the impact of non-uniform etch patterns may be at least partially compensated for by altering the implant dose with a corresponding spatial variation.

Ion implantation is a physical process, as opposed to diffusion, which is a chemical process that is employed in semiconductor apparatus fabrication to selectively implant dopant into a semiconductor workpiece and/or wafer material. Thus, the act of implanting does not rely on a chemical interaction between a dopant and the semiconductor material. For ion implantation, dopant atoms/molecules are ionized and isolated, sometimes accelerated or decelerated, formed into a beam, and swept across a workpiece or wafer. The dopant ions physically bombard the workpiece, enter the surface and typically come to rest below the workpiece surface in the crystalline lattice structure thereof.

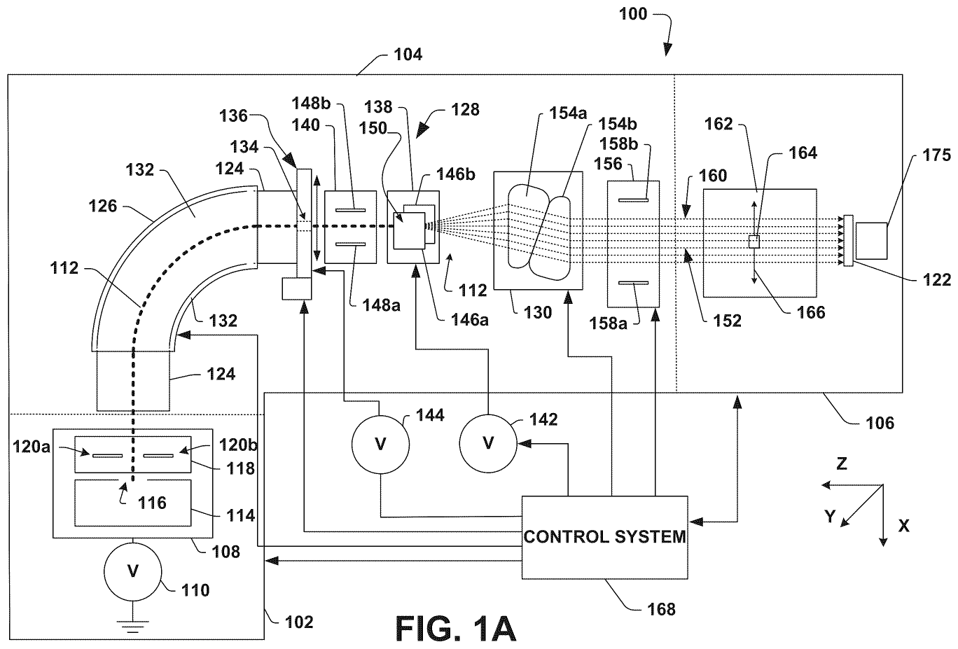

Referring now to the Figures, FIG. 1A is a schematic of an example ion implantation system 100 in accordance with an aspect of the present disclosure. The system 100 is presented for context and illustrative purposes, and it is appreciated that aspects of the invention are not limited to the described ion implantation system and that other suitable ion implantation systems of varied configurations can also be employed.

The system 100 has a terminal 102, a beamline assembly 104, and an end station 106. The terminal 102 includes an ion source 108 powered by a high voltage power supply 110 that produces and directs an ion beam 112 having a selected species to the beamline assembly 104. The ion source 108 generates charged ions that are extracted and formed into the ion beam 112, which is directed along a beam path in the beamline assembly 104 to the end station 106.

To generate the ions, a gas of a dopant material (not shown) to be ionized is located within an ion generation chamber 114 of the ion source 108. The dopant gas can, for example, be fed into the ion generation chamber 114 from a gas source (not shown). In addition to power supply 110, it will be appreciated that one or more suitable mechanisms (not shown) can be used to excite free electrons within the ion generation chamber 114, such as, for example, RF or microwave excitation sources, electron beam injection sources, electromagnetic sources and/or a cathode which creates an arc discharge within the chamber. The excited electrons collide with the dopant gas molecules and ions are generated thereby. Typically, positive ions are generated although the disclosure herein is applicable to systems wherein negative ions are generated as well.

The ions are controllably extracted through a slit 116 in the ion generation chamber 114 by an ion extraction assembly 118, in this example. The ion extraction assembly 118 comprises a plurality of extraction and/or suppression electrodes 120a, 120b. The ion extraction assembly 118 can include, for example, a separate extraction power supply (not shown) to bias the extraction and/or suppression electrodes 120a, 120b to accelerate the ions from the ion generation chamber 114. It can be appreciated that since the ion beam 112 comprises like-charged particles, the beam may have a tendency to expand radially outwardly as the like charged particles repel one another. It can also be appreciated that beam expansion can be exacerbated in low energy, high current (high perveance) beams where many like charged particles (e.g., high current) are moving in the same direction relatively slowly (e.g., low energy) such that there is an abundance of repulsive forces among the particles, but little particle momentum to keep the particles moving in the direction of the beam path. Accordingly, the ion extraction assembly 118 is generally configured so that the beam is extracted at a high energy so that the beam does not expand unduly (e.g., so that the particles have sufficient momentum to overcome repulsive forces that can lead to beam expansion). Moreover, the beam 112, in this example, is generally transferred at a relatively high energy throughout the system 100 and is reduced just before a workpiece 122 held on a workpiece support 175 positioned in the end station 106 to promote beam containment. The workpiece target in this case is where workpiece 122 is located or where it is configured to be located on the workpiece support 175.

In the example of FIG. 1A, the beamline assembly 104 in the present example has a beamguide 124, a mass analyzer 126, a scanning system 128, and a parallelizer and/or corrector component 130 (referred to generally as a parallelizer). The mass analyzer 126 performs mass analysis and angle correction/adjustment on the ion beam 112. The mass analyzer 126, in this example, is formed at about a ninety-degree angle and comprises one or more magnets (not shown) that serve to establish a (dipole) magnetic field therein. As the beam 112 enters the mass analyzer 126, it is correspondingly bent by the magnetic field such that ions of an inappropriate charge-to-mass ratio are rejected. More particularly, ions having too great or too small a charge-to-mass ratio are deflected into side walls 132 of the mass analyzer 126. In this manner, the mass analyzer 126 mainly allows those ions in the beam 112 which have the desired charge-to-mass ratio to pass there-through and exit through a resolving aperture 134 of a mass resolving aperture assembly 136, details of which will be discussed further infra.

The mass analyzer 126 can perform angle corrections on the ion beam 112 by controlling or adjusting an amplitude of the magnetic dipole field. This adjustment of the magnetic field causes selected ions having the desired/selected charge-to-mass ratio to travel along a different or altered path. As a result, the resolving aperture 134 can be adjusted according to the altered path. In one example, the mass resolving aperture assembly 136 is movable about an x direction (e.g., a direction transverse to the ion beam 112) so as to accommodate altered paths through the resolving aperture 134.

It will be appreciated that collisions of the ion beam 112 with other particles in the system 100 can degrade beam integrity. Accordingly, one or more pumps (not shown) may be included to evacuate, at least, the beamguide 124 and mass analyzer 126.

The scanning system 128 in the illustrated example includes a magnetic scanning element 138 (also referred to as an ion beam scanner, and in embodiments can be either magnetic or electrostatic) and a focusing and steering element 140. Respective power supplies 142, 144 are operatively coupled to the magnetic scanning element 138 and the focusing and steering element 140 and, more particularly, to respective electromagnets 146a, 146b and electrodes 148a, 148b located therein.

The focusing and steering element 140 receives the mass analyzed ion beam 112 having a relatively narrow profile (e.g., a “pencil” beam). A voltage applied by the power supply 144 to the electrodes 148a and 148b operates to focus and steer the beam to a scan vertex 150 of the magnetic scanning element 138. A voltage waveform applied by the power supply 142 (which could be the same supply as 144) to the electromagnets 146a and 146b then scans the beam 112 back and forth, in this example, therein defining a scanned ion beam 152 (sometimes called a “ribbon beam”). It will be appreciated that the scan vertex 150 can be defined as the point in the optical path from which each beamlet or scanned part of the ion beam 112 appears to originate after having been scanned by the magnetic scanning element 138.

The scanned ion beam 112 is then passed through the parallelizer 130, which comprises two dipole magnets 154a, 154b in the illustrated example. The two dipole magnets 154a, 154b, for example, are substantially trapezoidal and are oriented to mirror one another to cause the beam 112 to bend into a substantially s-shape. Stated another way, the two dipole magnets 154a, 154b have equal angles and radii and opposite directions of curvature.

The parallelizer 130 causes the scanned ion beam 112 to alter its path such that the ion beam travels parallel to a beam axis regardless of the scan angle. As a result, the implantation angle is relatively uniform across the workpiece 122.

One or more deceleration stages 156 are located downstream of the parallelizer 130 in this example. Up to this point in the system 100, the ion beam 112 is generally transported at a relatively high energy level to mitigate the propensity for beam expansion, which can be particularly high where beam density is elevated such as at the scan vertex 150, for example. The one or more deceleration stages 156, for example, comprise one or more electrodes 158a, 158b operable to decelerate the beam 112. The one or more electrodes 158a, 158b are typically apertures thru which the ion beam 112 travels, and may be drawn as straight lines in FIG. 1A.

Nevertheless, it will be appreciated that while two electrodes 120a and 120b, electromagnets 146a and 146b, electrodes 148a and 148b and 158a and 158b are respectively illustrated in the exemplary ion extraction assembly 118, the magnetic scanning element 138, focusing and steering element 140, and deceleration stage 156, these elements may respectively comprise any suitable number of electrodes arranged and biased to accelerate and/or decelerate ions, as well as to focus, bend, deflect, converge, diverge, scan, parallelize and/or decontaminate the ion beam 112, such as is provided in U.S. Pat. No. 6,777,696 to Rathmell et al. the entirety of which is hereby incorporated herein by reference. Additionally, the focusing and steering element 140 may comprise electrostatic deflection plates (e.g., one or more pairs thereof), as well as an Einzel lens, quadrupoles and/or other focusing elements to focus the ion beam.

The end station 106 then receives the ion beam 112 which is directed toward the workpiece 122. It is appreciated that different types of end stations 106 may be employed in the ion implantation system 100. For example, a “batch” type end station can simultaneously support multiple workpieces 122 on a rotating workpiece support structure, wherein the workpieces are rotated through a beam path 160 (also called a beamline) of the ion beam 112 until all the workpieces are completely implanted. A “serial” type end station, on the other hand, supports a single workpiece 122 along the beam path 160 for implantation, wherein multiple workpieces are implanted one at a time in serial fashion, with each workpiece being completely implanted before implantation of the next workpiece begins. In hybrid systems, the workpiece 122 may be mechanically translated in a first direction (the y-direction or so-called “slow scan” direction) while the ion beam 112 is scanned in a second direction (the x-direction or so-called “fast scan” direction) to impart the beam 112 over the entire workpiece 122.

In an example, a workpiece support 175 is coupled to a mechanical beam-to-workpiece translation system that moves the workpiece 122 in relation to the beam 112 in either an x-direction, a y-direction, or x- and y-direction. This is an alternative to a beam-to-workpiece translation system that scans the beam 112 across one or more dimensions of the workpiece 122. A hybrid system may also be utilized as described above. For purposes of the presently disclosed technology, whether the beam 112 is scanned or the workpiece 122 is moved, the speed and positioning of the beam 112 in relation to the workpiece 122 (the beam-to-workpiece speed and position) is of interest.

The end station 106 in the illustrated example is a “serial” type end station that supports the single workpiece 122 along the beam path 160 for implantation. A dosimetry system 162, for example, is included in the end station 106 near the location of the workpiece 122 for measurements of the ion beam 112 (e.g., measurements may be performed prior to implantation operations). During calibration, the beam 112 passes through dosimetry system 162. The dosimetry system 162, for example, includes one or more profilers 164 that may continuously traverse a profiler path 166, thereby measuring the profile of the scanned ion beam 152.

The one or more profilers 164, for example, may comprise a current density sensor, such as a Faraday cup, that measures the current density of the scanned ion beam 152, where current density is a function of the angle of implantation (e.g., the relative orientation between the ion beam and the mechanical surface of the workpiece 122 and/or the relative orientation between the ion beam and the crystalline lattice structure of the workpiece). The current density sensor, for example, moves in a generally orthogonal fashion relative to the scanned ion beam 152 and thus typically traverses the width of the scabbed ion beam. The dosimetry system 162, in one example, measures both beam density distribution and angular distribution. The dosimetry system 162 may also measure beam shape.

A control system 168 (also called a controller) is further provided to control, communicate with, and/or adjust the ion source 108, the mass analyzer 126, the mass resolving aperture assembly 136, the magnetic scanning element 138, the parallelizer 130, and the dosimetry system 162. The control system 168 may comprise a computer, microprocessor, etc., and may be operable to take measurement values of characteristics of the ion beam 112 and adjust parameters accordingly. The control system 168 can be coupled to the terminal 102 from which the ion beam 112 is generated, as well as the mass analyzer 126 of the beamline assembly 104, the magnetic scanning element 138 (e.g., via power supply 142), the focusing and steering element 140 (e.g., via power supply 144), and the deceleration stage 156. Accordingly, any of these elements can be adjusted by the control system 168 to facilitate desired ion implantation.

In an example in accordance with the technology disclosed herein, the control system 168 controls the beam-to-workpiece target scan speed and the application of a mechanical or other gating mechanism. For example, the dosimetry system 162 controlled by the control system 168, may be utilized to gate (or shutter) the beam 112 during an implant at predetermined times in accordance with a desired implantation profile as the beam/wafer scan continues at a constant or varied speed.

The dosimetry system 162 controlled by the control system 168, may also be utilized to gate (or shutter) the beam 112 during an implant if the measured beam current is outside a tolerance range that is set in a process recipe for the particular ion implantation. For example, in a process recipe specifying a desired beam current of 20 ma with a predetermined range of +−10%, the control system 168 may be configured to close the resolving aperture assembly 136 to shutter and hold the implant, should the measured beam current fall below 18 ma or exceed 22 ma.

An additional measurement system (not shown, but similar to the dosimetry system 162) may be further used in conjunction with dosimetry system 162 in order to detect fast transients or glitches in the beam 112 that would otherwise go undetected by the dosimetry system 162. During a glitch, for example, the beam 112 is switched off, the resolving aperture assembly 136 will close or shutter, and the implant will be kept on hold until the ion beam is stable. For example, U.S. Pat. No. 7,507,977 to Weiguo, et al. describe a system and method of controlling an ion beam in response to an ion beam glitch.

The strength and orientation of magnetic field(s) generated in the mass analyzer 126 can be adjusted, such as by regulating the amount of electrical current running through field windings therein to alter the charge to mass ratio of the beam, for example. The angle of implantation can be controlled by adjusting the strength or amplitude of the magnetic field(s) generated in the mass analyzer 126 in coordination with the mass resolving aperture assembly 136. The control system 168 can adjust the magnetic field(s) of the mass analyzer 126 and position of the resolving aperture 134 according to measurement data from, in this example, the profiler 164. The control system 168 can verify the adjustments via additional measurement data and perform additional adjustments via the mass analyzer 126 and the resolving aperture 134, if necessary.

In accordance with technology disclosed herein for providing non-uniform dosage profiles, the ion implantation system 100 includes a gating device for blocking the ion beam 112 from traveling further downstream toward the end station 106 or from travelling to the workpiece 122. This can be accomplished with a power control gating device or a mechanical gating device. Another method of gating the beam away from the workpiece target is to change the beam energy so it does not reach the workpiece target or deflecting the beam, so it no longer reaches the workpiece target. Deflection can be accomplished by a magnetic, electric, or electromagnetic beam deflection apparatus. The term beam gating is used herein to include this type of deflection, but may be referred to more specifically as “beam parking.”

In an example shown in FIG. 1A, a mechanical gating device is a resolving aperture assembly 136 that may be employed to provide a fast-acting shutter motion for the resolving aperture 134 that functions to gate (i.e., shutter or block) the ion beam 112 from traveling further downstream toward the end station 106. As disclosed herein, the beam-to-workpiece target position (which can be induced by either the beam scan or workpiece/workpiece support movement) continues to change while the beam is gated. This is in contrast to glitch detection, wafer placement, and other processes where the beam is gated and ungated to maintain a uniform dose or the scanning motion is stopped to correct the glitch.

In an example, at least two types of mechanical gating devices can accomplish the mechanical gating (or shuttering) of a still activated ion beam 112; namely, a rotatable shutter similar to a ball valve, and a resolving plate having one or more fixed-width apertures, whereby the desired aperture is generally positioned in the center of the beamline. These have the benefit of also allowing for control of the width of the resolving aperture. An example of a multiple-aperture plate is provided in commonly owned U.S. Pat. No. 7,399,980 to Vanderberg et al., the contents of which are incorporated by reference in its entirety, herein. Such a multiple-aperture plate provides several discrete widths of resolving apertures, while further providing an ability to move the resolving aperture transverse to the ion beam in order to modify or correct angular orientations of the ion beam.

In an example, the single resolving aperture assembly 136 is configured to and to selectively gate (shutter) the ion beam 112 from being transported beyond the resolving aperture assembly 136 in accordance with the technology disclosed herein. In addition, the resolving aperture assembly 136 can provide a selective variation of the width of the resolving aperture 134, to selectively vary the relative location of the resolving aperture across (e.g., transverse in the x-direction) and along (e.g., in the z-direction) the beam path 160.

Other apparatuses for beam gating include high voltage fast switches on power supplies. Such devices are faster than mechanical apertures or redirection and can be more precise in the speed between the beam cutting on and off from the workpiece.

FIG. 1B discloses an example of a power control gating device. In FIG. 1B an example beam control circuit 200 of an ion implantation system is used to initiate or terminate the ion beam by switching the extraction and/or suppression voltages to the extraction and/or suppression electrodes associated with the ion source of an ion implantation system, such as the ion implantation system 100 of FIG. 1A.

Beam control circuit 200 comprises an extraction or suppression voltage supply V 203, such as extraction voltage VE, or suppression voltage VS, respectively. The beam control circuit 200 further comprises a high voltage high speed (HVHS) switch 204, a switch controller 208 for opening and closing the HVHS switch 204 connected between the voltage supply 203 and an electrode 211 of an ion source 220 used for producing a quantity of ions that can be extracted in the form of an ion beam.

The beam control circuit 200 further comprises one or more parallel and/or series protection circuits 210 and 215, respectively, to absorb energy from reactive components surrounding the HVHS switch 204 and to protect the switch from over-voltage damage. The protection circuits 210 and 215 also protect the HVHS switch 204 and other components of the ion implanter, by dampening any ringing or other such overvoltages induced by switching transients and the reactive components external to the HVHS switch 204. The beam control circuit 200 may be used in any ion implanter, or other applications such as may require beam control, or for example, circuits which use a high voltage supply subject to arc discharges at the electrodes or at the output of the supply.

The beam control circuit 200 operates by receiving an external On or Off command 208a or by receiving a sync input command 208b from other such switch controllers (switch circuits) into the switch controller 208. The switch controller 208 then closes the HVHS switch 204 prior to the start of ion implantation to connect Va of the electrode 211 of ion source 220 to Vb of voltage supply 203 for production of the ion beam. Then after the conclusion of the ion implantation, the switch controller 208 opens the HVHS switch 204 again. When the HVHS switch 204 opens, any overvoltages produced by the reactive components of the beam control circuit 200, are absorbed by protection circuits 210 and 215, and Va at the electrode 211 drops to near zero and terminates the ion beam. In this way, the beam control circuit 200 reduces the beam duty factor or on-time of the ion beam of the ion implantation system.

In an example, an ion implantation system may have two such switches, one for the extraction power supply and the other for the suppression power supply. The above two switches may be synchronized by the switch controller 208.

The scheme of FIG. 1B has a fast time to start and stabilize the ion beam, and can be as fast as about 1 ms, or in other examples 0.75 ms to 30 ms, such as 0.8 to 10 ms, or 0.9 to 3 ms. Other switches and associated systems and methods can be used for quickly gating the ion beam on and off; for example, those disclosed in U.S. Pat. No. 7,566,887, which is incorporated herein by reference. Beam parking devices, such as electric, electromagnetic, or magnetic deflection devices may also be used, as mentioned above.

Beam-to-workpiece target speed can be varied in this and other ion implantation systems. Some systems can vary the speed of the beam scan across the workpiece target. Other systems can vary the speed of the beam-to-workpiece target by varying the movement of the workpiece/workpiece support, while the beam stays in a static location. Some systems are capable of varying beam scan speed and workpiece support/workpiece movement. The beam-to-workpiece target speed can be modified in increments depending on the system. Typically, a system's beam-to-workpiece target speed may vary in 10% increments. A system's minimum speed may be 1/10 of its maximum speed.

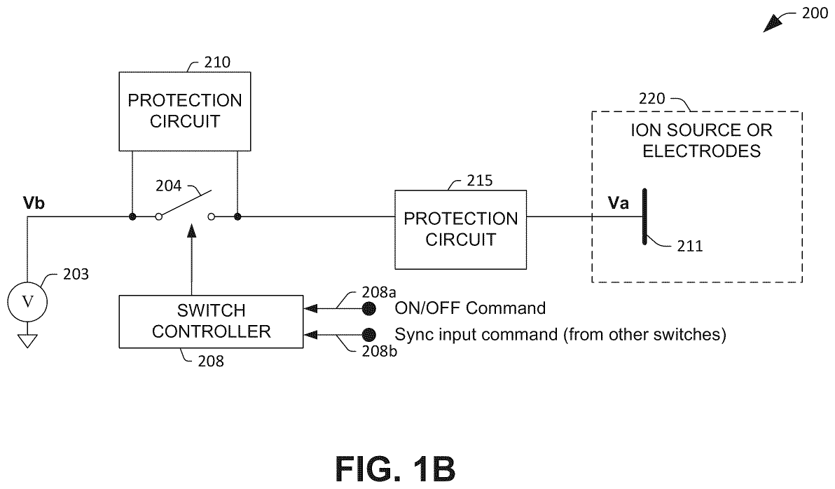

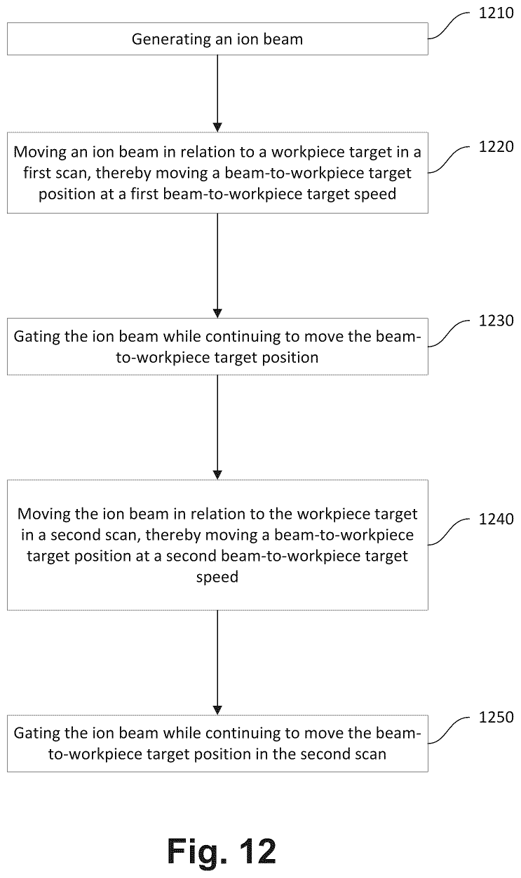

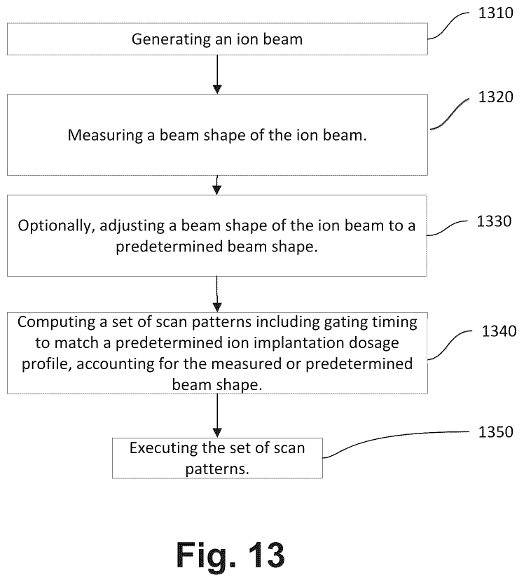

In reference now to FIGS. 2-13, the methodology associated with the gated ion implantation system will be further described, first in detailed explanatory terms, in FIGS. 2-11 and then in a more generalized summary form in FIGS. 12 and 13.

FIG. 2 is a graph showing a desired dose profile in comparison to a required beam-to-workpiece target speed profile. The x-axis is wafer position and the y-axis is relative dose and relative scan speed. As a first example, FIG. 2 considers a case where the desired dose profile is a “notch.” In particular, the notch is some percentage of the normal dose, for example 10% (corresponding to 2.5× relative velocity) of the dose of the remainder of the wafer (corresponding to 0.25× relative velocity) or a 90% drop in relative dose. This profile can be accomplished to obtain a 0.25 dose in the notch, and a 2.5 relative dose in the un-notched sections. This can be done by varying the beam-to-workpiece target speed as shown. However, this requires a range of speed at a minimum being 1× and a maximum speed being 10×. If this speed variation exceeds the bandwidth of the system, then the implantation system would not be able to provide the desired dose profile. Notably, even though multiple passes could be made with this technique to try and approximate the desired profile, the ratio of the lowest dosage of the notch to the highest dosage in the un-notched sections would not be different even with multiple passes.

The technology disclosed herein provides the ability to address such situations where the desired profile is outside the ability of the ion implantation system to achieve through beam-to-workpiece target speed variation. This is to provide dose variation through multiple passes (dose characteristics of a pass are referred to as a “pattern”) including beam gating within an ion implantation system to provide the predetermined dose profile.

As another example of a desired profile unachievable by conventional beam-to-workpiece target speed variation, assume that the ion implantation system has the capability of adequately changing the beam-to-workpiece target scan speed, e.g., 1× to 10×, but is not able to do so quickly enough to provide desired sharp edges in a profile. The technology discloses herein can be used, in an example, to gate the ion beam quickly on to off or vice-versa while the beam-to-workpiece target position moves as little as 0.05 mm, such as, for example, 0.06 to 1 mm, or 0.1 to 0.85 mm. The beam can be gated on or off in, for example, in as little as 1 millisecond, such as, 2 milliseconds to 10 milliseconds, or 3 milliseconds to 5 milliseconds.

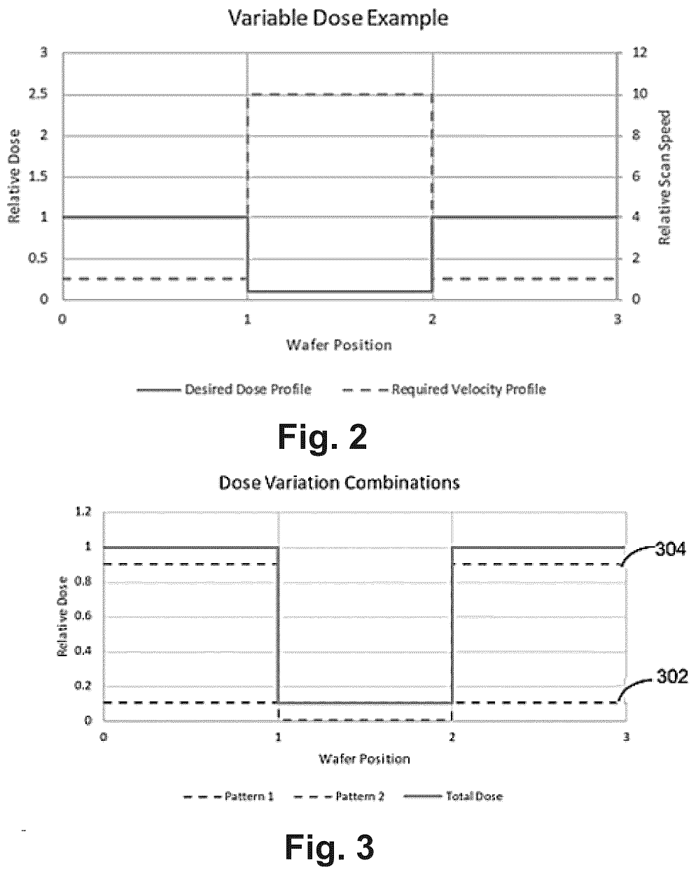

FIG. 3 is a graph showing a desired total dose profile overlaid with a first pattern 302 and a second pattern 304 with the relative dose on the y-axis and the wafer position on the x-axis. In this case, the desired pattern represented by the total dose could be achieved with the technology disclosed herein by combining a first pattern 302 with the beam or wafer scanning uniformly at a maximum scan speed that provides 10% of the dose. A second pattern 304 is also provided with a uniform beam-to-workpiece target speed that provides 90% of the dose but with a notch induced by a gating mechanism at the desired location. The gating mechanism, provided it is a non-mechanical mechanism, can provide a sharp notch in the profile.

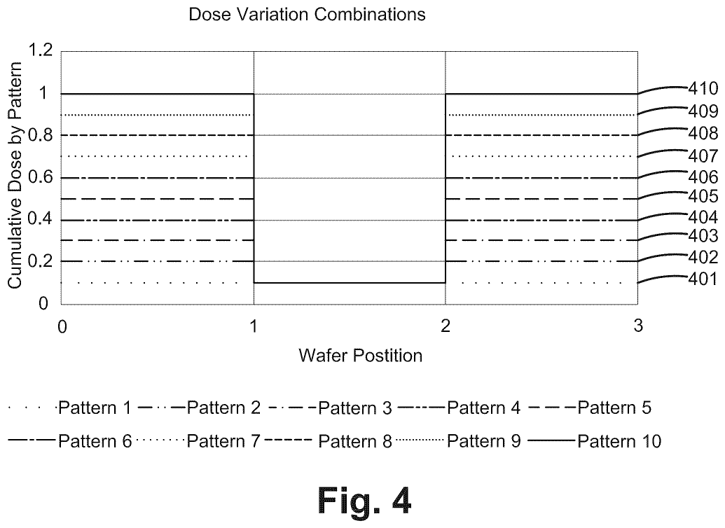

FIG. 4 is a graph showing first through tenth patterns 401-410 with the relative dose on the y-axis and the wafer position on the x-axis. Each of the first through tenth patterns are ran at the same scan speed. In contrast to the profile of FIG. 3 which assumes that the first pattern 302 and second pattern 304 use a different beam to wafer speed, such a multi-speed approach might not always be possible or desirable. As illustrated in FIG. 4, the desired pattern could be achieved by a first uniform speed pattern at 10% (e.g., max speed scan) of the total dose and 9 additional patterns with the same beam-to-workpiece target speed with a gate-induced notch.

More complex profiles than a simple notch with sharp sides can also be produced through the methodology disclosed herein. If the desired function is not a notch, then through selective, variable gating, the notch width on each pattern can be varied to produce a combination pattern that replicates or approximates the desired dose function. Non-uniform beam-to-workpiece target scan speeds can be used to accomplish certain effects in dosage profiles, varying speed either within a scan pattern or between scan patterns.

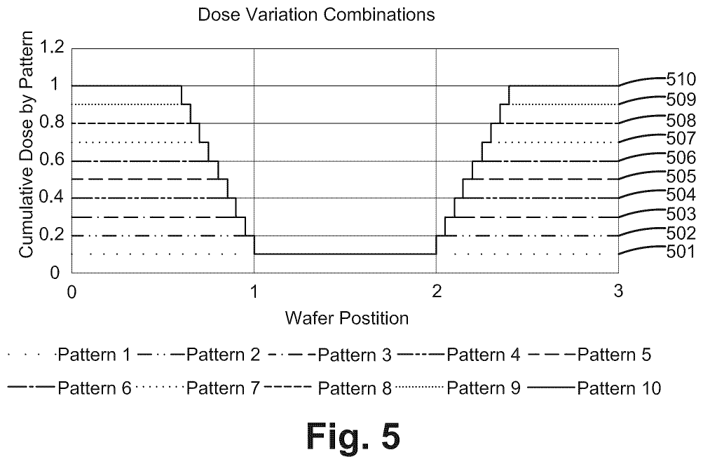

For example, FIG. 5 discloses a profile approximating a notch with linearly sloped edges. FIG. 5 is a graph like FIG. 4 showing first through tenth patterns 501-510 with the relative dose on the y-axis and the wafer position on the x-axis. The difference is the gating mechanism is timed to activate and deactivate at different times for each pattern. A first pattern 501 provides a uniform scan rate and dose. Then, in successive scans 502 to 510 a gate is activated progressively earlier and later in the scan pattern (gated on earlier and gated off later). This provides a V-shaped notch in the ion implantation profile with the sides of the notch narrowing from a high dosage, (e.g., at a cumulative relative dose of 1) at wafer positions 0 to 0.7 down to a low dosage (e.g., at a cumulative relative dose of 0.1) at wafer position 1 to 2. The second side of the notch rises at wafer position 2 back to a high dose (cumulative relative dose of 1) at wafer position 2.3 where it continues at the high does to wafer position 3.

Wafer position as described herein can also be equated to workpiece target position. As such, it can be seen that the ion beam can gated by the gating apparatus at a same workpiece target position or a different workpiece target position in a first scan and a second scan (or subsequent additional scans).

The plots and profiles described in FIGS. 2-5 are simplified representations that assume an ideal case where the beam size is small compared to the dose feature, but in practice this is not typically the case. The beam diameter in the direction of the scanning will affect the notch shape. Thus, if the beam shape is known, then the actual dose pattern can be modeled and the pattern widths modified to produce an actual pattern that is closer to the desired pattern.

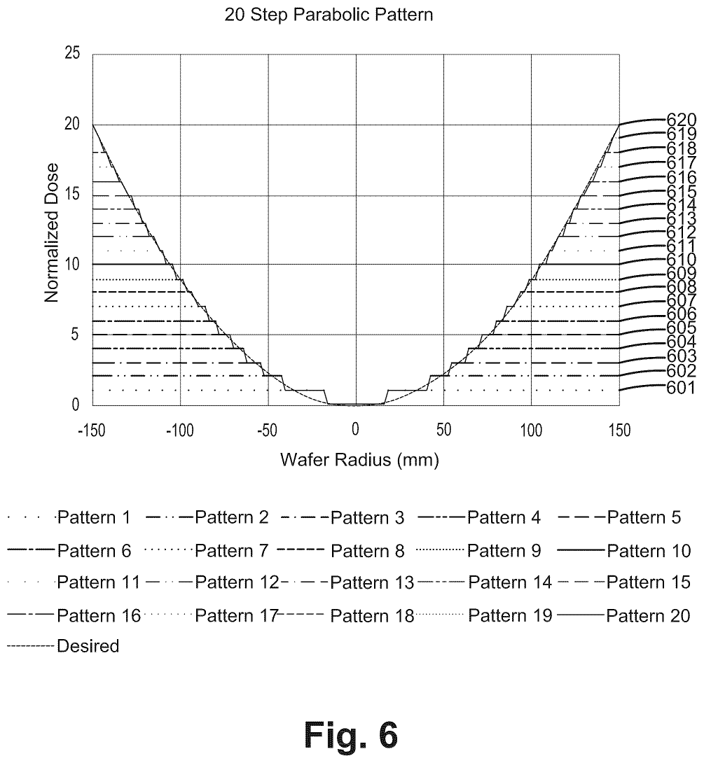

FIG. 6 is a graph showing first through twentieth patterns 601-620 with the normalized dose on the y-axis and the wafer position on the x-axis. This example discloses the case of a desired parabolic dose profile constructed using 20 patterns. In FIG. 6, like in FIGS. 2-5, the beam shape is not accounted for, or is considered to be very small. Here the dose patterns are determined by a simple best fit of each pattern to the desired dose profile not accounting for the beam shape. This simple model is a reasonable best-fit for a beam with a small profile in the mechanical scan direction, e.g., a dimension of 0.1 mm to 10 mm, such as, 0.2 mm to 2 mm, or 0.5 mm to 1 mm. However, when a larger beam, e.g., 10 to 150 mm, 25 to 125 mm, or 50 to 100 mm, is used the proposed pattern loses accuracy in actual dosages.

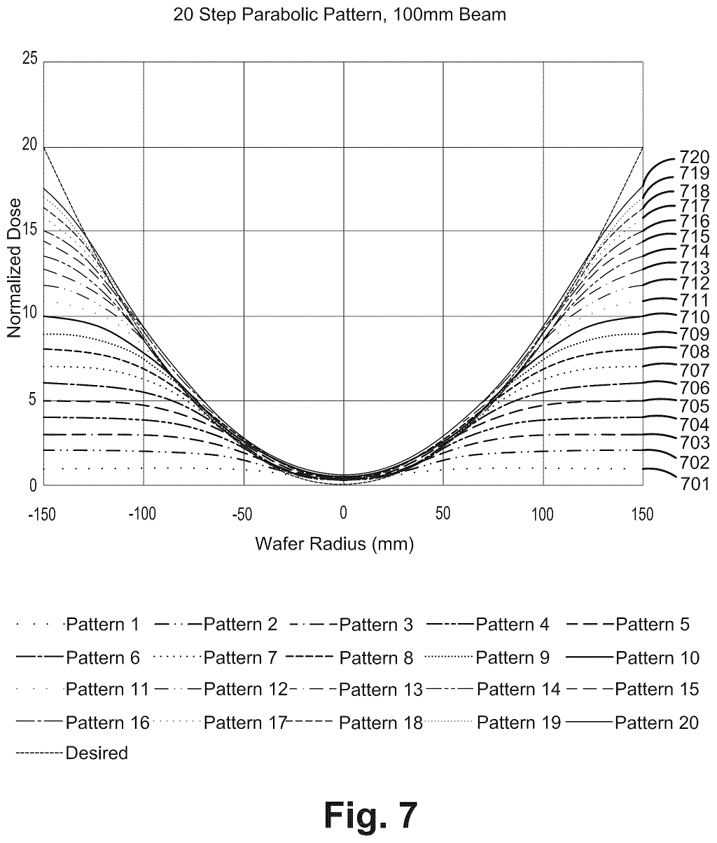

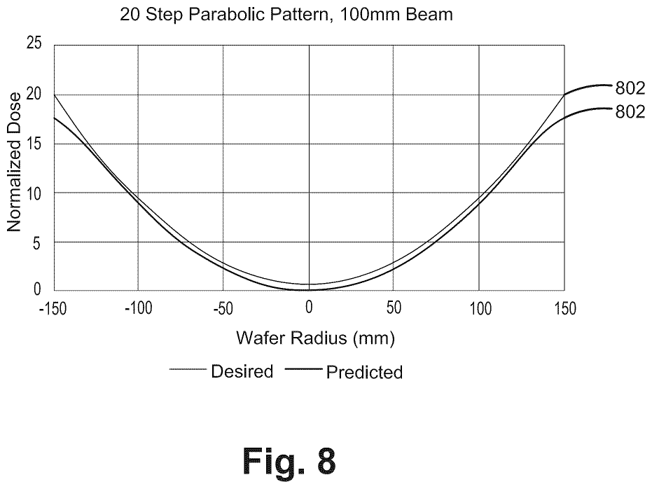

FIG. 7 is a graph showing first through twentieth patterns 701-720 with 100 mm beam with the normalized dose on the y-axis and the wafer position on the x-axis. In contrast to FIG. 6, FIG. 7 shows the effect of using a larger beam diameter. The actual dosage loses accuracy with the larger beam and the variation from the desired parabolic line is greater in FIG. 7 than FIG. 6. In particular, the top corners of the actual dosage profile are lower in dosage than the desired parabolic dosage profile and the lowest portion (especially at the trough) of the actual dosage profile is greater than the desired parabolic shape. This difference can be better seen in FIG. 8. FIG. 8 is a graph like FIG. 7 but with the patterns removed, showing just the desired and predicted actual doses with a 100 mm beam.

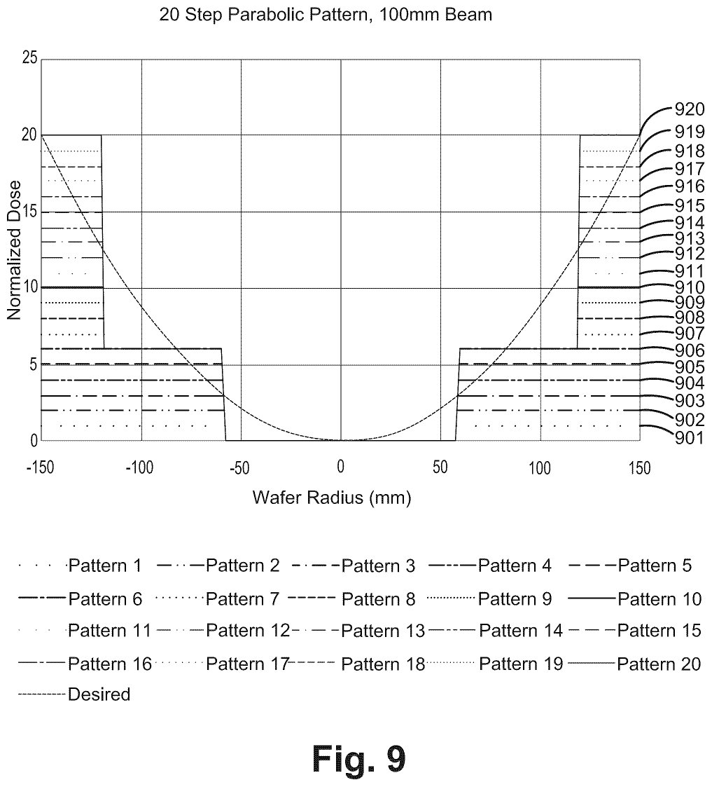

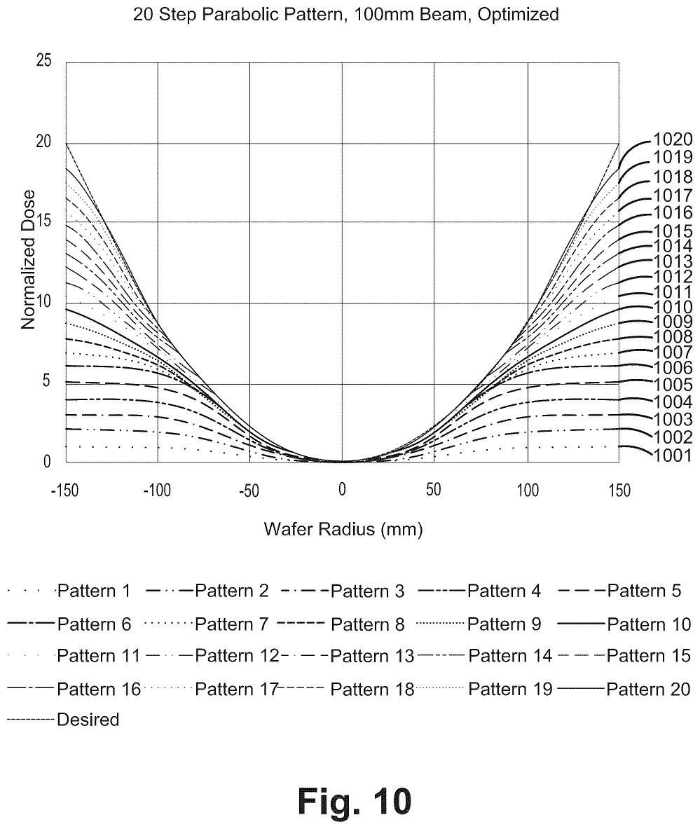

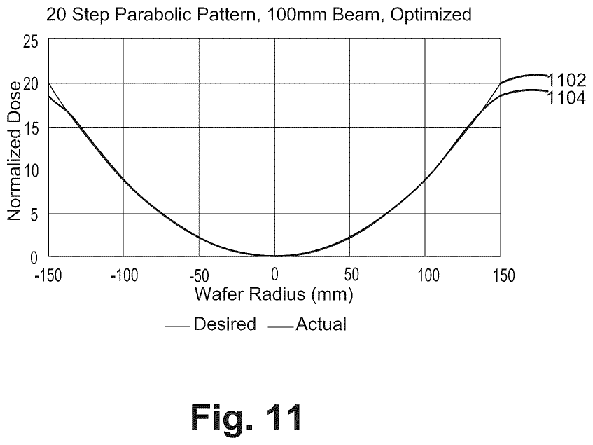

In the Figures above the dose profile assumes a small beam, but FIG. 9, FIG. 10 and FIG. 11 account for the beam size. The improvement in desired and predicted doses are improved compared to the graphs above. In order to provide a better actual dosage fit to the desired profile, the beam shape effect can be modeled by various computational methods. Thus, with a known beam profile, it is possible to use a computed matrix solution to determine a best fit to the desired profile. This effect can actually be used to take advantage of the blurring or smoothing characteristics of a larger beam and produce a smooth curve fit to a desired profile.

FIG. 9 is a graph showing first through twentieth patterns 901-920 with the normalized dose on the y-axis and the wafer position on the x-axis. Surprisingly, a best-fit dosage profile to match a parabolic shape accounting for a 100 mm beam diameter calls for two step gating on each side of the notch. Here, patterns 901 to 906 are synchronized to be gated at the same time in the beam scan, i.e., when the scan reaches about −55 mm on the wafer on a first side of the notch and about +55 on the second side of the notch (wherein the 0 position is set at the middle of the notch). Patterns 907 to 920 are synchronized to be gated at the same time in the beam scan, i.e., when the scan reaches about −55 mm on the wafer on a first side of the notch and about +55 on the second side of the notch.

In FIG. 9 the set of scan patterns and the gated timing were calculated to match the desired profile by the following dose calculations.

The implanted dose at a point on a wafer in one dimension can be predicted from the equation:

$${D}_{x} = \frac{1}{e} * \int \frac{f ( {I}_{t} )}{f ( {S}_{t} )} d t$$

where:
Dₓ=dose at point x
f(Iₜ)=an anticipated instantaneous beam current density in x and any induced variations in beam current such as with gating the beam at prescribed times or positions
f(Sₜ)=an anticipated beam to wafer speed variation in x such as continuing to scan during beam gating operations or changing the speed with beam current to modify the dose
e=charge of an electron

If the wafer has more than one pass through the beam then the total dose is the summation of the doses based on the equation above with potentially variable beam current density and speed profiles by wafer pass:

$$Total {Dose}_{x} = {\sum }_{i = 1}^{n} \frac{1}{e} * \int \frac{{f ( {I}_{t} )}_{i}}{{f ( {S}_{t} )}_{i}} d t$$

Where n is defines each pass of the wafer through the beam and with the anticipated beam density and beam speed variations for each pass.

The desired dose profile in x can then be calculated based on the total dose at x based on the equation above. An iterative solution for f(Iₜ)ᵢ and f(Iₜ)ₜ can be employed to determine the best fit to the desired dose profile.

FIG. 10 shows the calculated ion implantation dosage on a wafer after a set of patterns as shown in FIG. 9 produced.

FIG. 11 is a graph like FIG. 10 but with the patterns removed, showing just the desired 1102 and empirically measured actual 1104 observed doses with a 100 mm beam. The actual 1104 observed dose was measured using sheet resistance, a well-known technique for measuring implant dose. The close curve fit achieved by this method with a large beam of 100 mm is superior to the curve fit achieved by accounting for the beam shape. (Compare to FIG. 8.)

Note that although multiple passes with uniform scan speed are disclosed in the examples of FIG. 4-11 this is not required, and dose patterns and speeds that are within the bandwidth of the system could be combined to provide more flexibility.

FIGS. 2-11 disclose sharp notch dose profiles, V-shaped with flat bottom profiles, and parabolic-shaped profiles. Other shaped profiles can be implanted with the technology disclosed herein also. Other examples profiles include symmetrical and non-symmetrical U-shapes, V-shapes, wave shapes, curves, and other non-symmetrical profiles. The dosage profile can be repeated as desired throughout the wafer, i.e., at other workpiece target position ranges on the wafer. Various dosage profiles may be desired for particular end applications.

FIG. 12 is a flowchart of an example method for conducting ion implantation. At step 1210, an ion beam is generated. This can be done in various ways as previously discussed. It should be understood that these operations of the ion implantation system as well as other operations can be controlled by a controller that is operatively associated with the various components of the system.

At step 1220, the ion beam is moved in relation to a workpiece target in a first scan, thereby moving a beam-to-workpiece target position at a first beam-to-workpiece target speed. The ion beam can be moved itself or the workpiece/workpiece support can be moved in order to move the ion beam in relation to the workpiece target position.

At step 1230, during a first scan, the ion beam is gated while continuing to move the beam-to-workpiece target position. Gating the ion beam refers to changing its off/on state and includes either gating it on, gating it off, or both. Gating can be accomplished by electrical, magnetic, electromagnetic deflection (beam parking), mechanical deflection, or power switching, as disclosed above.

At step 1240, the ion beam is moved in relation to the workpiece target in a second scan, thereby moving the beam-to-workpiece target position at a second beam-to-workpiece target speed. The second scan covers a same area of the workpiece target as the first scan. That is, the second scan overlays the first scan with additional ion implantation. The first and second beam-to-workpiece target speed can be the same or different. Furthermore, the first or second beam-to-workpiece target speed can be constant in a scan or vary during the duration of a scan. The terms “first” and “second” are meant to describe a relative order between the two scans, and not an absolute order. That is, the first scan referenced here is not necessarily the very first time the workpiece target has been scanned with an ion beam. There may have been one or more earlier scans (with or without gating).

At step 1250, during the second scan, the ion beam is gated while continuing to move the beam-to-workpiece target position. Additionally, more than two scans can take place, such as is illustrated in many of the Figures above. For example, 3 to 300 scans, 5 to 100 scans, or 10 to 25 scans can be performed to achieve the desired implantation profile. Higher iterations of scans may be utilized to provide more complex dosage profiles and to build up larger differences in total dosage in the scan area. For example, a first workpiece target position may receive a dose variation of at least 25% greater than a second workpiece target position, the second workpiece target position being closely adjacent, i.e., 0.05 mm, such as, for example, 0.06 to 1 mm, or 0.1 to 0.85 mm micrometers from the first workpiece target position. This is limited by the beam height, e.g., a 10 mm beam height would result in a 10 mm transition region from 0 to 100% dosage. In an example, this dose variation may be 50% to 10,000%, 75% to 1,000%, or 75% to 250%. The methods disclosed herein allow for a first workpiece target position to have no dose and an adjacent second workpiece target position to have a substantial dose, e.g., 2×10¹³ to 1×10¹⁴ ions/cm², such as, for example, 3×10¹³ to 8×10¹³, or 4×10¹³ to 6×10¹³ ions/cm². The second workpiece target position may be closely adjacent, i.e., 0.05 mm, such as, for example, 0.06 to 1 mm, or 0.1 to 0.85 mm micrometers from the first workpiece target position. Thus, within as little as 0.05 mm, the dosage may vary from a first workpiece target position to a second workpiece target position by, for example, 5×10¹³ ions/cm². A typical total dose for the workpiece would be on the order 1×10¹⁵ (equating to 20 passes), such as 3×10¹³ to 8×10¹³ ions/cm².

FIG. 13 is a flowchart of an example method for conducting ion implantation. FIG. 13 focuses on the beam shape measurement and adjustment, and calculation of a set of scan patterns to achieve a predetermined ion implantation dosage.

At step 1310, an ion beam is generated. This can be done in various ways as previously discussed.

At step 1320, the beam shape of the ion beam is measured. To time the gating correctly to match the desired dosage profile the beam shape should be known. While a general beam shape can be known from a standard setting, if more accuracy is desired, real-time beam monitoring, measurement and adjustment can be performed on the ion implantation system. In an example system, a multi-cup measurement device can be utilized to measure, monitor, and show the beam height and width. In an example, control software, such as that used for providing uniform implantation beam dosages, can perform such analysis and conform the beam to a predetermined and consistent shape through a looped tuning process. This can be used to improve the process, such as by reducing the number of passes or fine-tuning precision.

At step 1330, the beam shape of the ion beam can optionally be adjusted to a predetermined beam shape. If the beam shape is already measured to be within the parameters of what is expected, then no adjustment needs to take place. In addition, certain ion implantation devices may not have this ability to adjust the beam shape. In this case, the measured beam shape is not changed and is accounted for by the gating process to achieve the desired implantation profile in the next step.

At step 1340, computing a set of scan patterns including gating timing to match a predetermined ion implantation dosage profile, accounting for the measured or adjusted and predetermined beam shape. An example of such calculations is disclosed above. Control software can be used to instruct the controller to generate the set of scan patterns needed to achieve the desired ion implantation dosage profile.

At step 1350, set of scan patterns are executed. This is done by the multi-pass ion beam scanning and gating the beam on and off at appropriate times. The scan patterns may also include variation in the beam-to-workpiece target speed from scan pattern to scan pattern, or varying the speed during a scan pattern.

Although the disclosure has been shown and described with respect to a certain applications and implementations, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure, which performs the function in the herein illustrated exemplary implementations of the disclosure.

In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “including”, “has”, “having”, and variants thereof are used in either the detailed description or the claims, these terms are intended to be inclusive in a manner similar to the term “comprising.”

What is claimed is:

1. An ion implantation system, comprising:
an ion source that generates ions and produces an ion beam along a beamline;
a workpiece target associated with the beamline;
a controller configured to control a beam-to-workpiece target translation mechanism to move the ion beam in relation to a workpiece target, thereby moving a beam-to-workpiece target position at a beam-to-workpiece target speed; and
a gating apparatus including one or more of:
a mechanical gating device configured to block or deflect the ion beam from being directed to the workpiece target;
a power control gating device configured to cut off power to the ion source; or
a magnetic, electromagnetic, or electric beam deflection device configured to deflect the ion beam from being directed to the workpiece target;
wherein the beam-to-workpiece target translation mechanism changes the beam-to-workpiece target position while the ion beam is gated by the gating apparatus.

2. The ion implantation system of claim 1, wherein the beam-to-workpiece target translation mechanism is either:
an electrostatic or magnetic based ion beam scanner; or
a mechanical device that moves the workpiece target;
and
the gating apparatus includes one or more of:
a mechanical gating device configured to block or deflect the ion beam from being directed to the workpiece target; or
a power control gating device configured to cut off power to the ion source.

3. The ion implantation system of claim 1, further comprising a controller, the controller configured to cause the beam-to-workpiece target translation mechanism to perform first and second scans of the workpiece target.

4. The ion implantation system of claim 3, wherein the beam-to-workpiece target speed is uniform for a duration of the first and second scans.

5. The ion implantation system of claim 3, wherein the beam-to-workpiece target speed is not uniform for a duration of the first scan.

6. The ion implantation system of claim 3, wherein the beam-to-workpiece target speed is different for the first scan and the second scan.

7. The ion implantation system of claim 3, wherein the ion beam is gated by the gating apparatus at a same workpiece target position in the first scan and the second scan.

8. The ion implantation system of claim 3, wherein the ion beam is gated by the gating apparatus at a different workpiece target position in the first scan and the second scan.

9. The ion implantation system of claim 1, further comprising a controller, the controller configured to cause the beam-to-workpiece target translation mechanism and gating apparatus to gate the ion beam as the beam-to-workpiece target position moves 1 to 150 mm.

10. A method of conducting ion implantation comprising:
generating an ion beam;
moving an ion beam in relation to a workpiece target in a first scan, thereby moving a beam-to-workpiece target position at a first beam-to-workpiece target speed; and
during the first scan, gating the ion beam while continuing to move the beam-to-workpiece target position.

11. The method of claim 10, further comprising moving an ion beam in relation to the workpiece target in a second scan, thereby moving the beam-to-workpiece target position at a second beam-to-workpiece target speed, wherein the second scan covers a same area of the workpiece target as the first scan; and
during the second scan, gating the ion beam while continuing to move the beam-to-workpiece target position.

12. The method of claim 11, wherein the gating of the ion beam in the second scan is conducted at a different beam-to-workpiece target position than the gating of the first scan.

13. The method of claim 10, further comprising gating the ion beam off and gating the ion beam on during the first scan.

14. The method of claim 10, wherein a beam-to-workpiece target speed is constant during the first scan.

15. The method of claim 10, wherein a beam-to-workpiece target speed is varied during the first scan.

16. The method of claim 10, wherein a first workpiece target position receives a dose variation of at least 25% greater than a second workpiece target position, the second workpiece target position being 0.05 to 1 mm from the first workpiece target position.

17. The method of claim 10, wherein a first workpiece target position has no dosage and a second workpiece target position has a dosage, the second workpiece target position being 0.05 mm from the first workpiece target position.

18. The method of claim 11, further comprising computing timing of the gating in the first and second scans to match a predetermined workpiece target dosage profile.

19. The method of claim 18, wherein a beam shape of the ion beam is accounted for in the computing of the gating in the first and second scans to match the predetermined workpiece target dosage profile.

20. The method of claim 18, wherein the predetermined workpiece target dosage profile is selected from the group consisting of a symmetrical or non-symmetrical: notch, parabola, V-shape U-shape, wave shape, curve, and other non-symmetrical shapes.
